(19) United States
(12) Patent Application Publication
(10) Pub. No.: US 2013/0271934 A1
(43) Pub. Date: Oct. 17, 2013

(54) ELECTRONIC DEVICE WITH CABLE MANAGEMENT APPARATUS

(71) Applicants: HONG FU JIN PRECISION INDUSTRY (SHENZHEN) CO., LT, Shenzhen (CN); HON HAI PRECISION INDUSTRY CO., LTD., New Taipei (TW)

(72) Inventors: YU-WEI HE, Shenzhen (CN); XIU-QUAN HU, Shenzhen (CN)

(73) Assignees: HON HAI PRECISION INDUSTRY CO., LTD., New Taipei (TW); HONG FU JIN PRECISION INDUSTRY (ShenZhen) CO., LTD., Shenzhen (CN)

(21) Appl. No.: 13/685,641

(22) Filed: Nov. 26, 2012

(30) Foreign Application Priority Data
Apr. 12, 2012 (CN) 201210106037.3

(51) Int. Cl. H05K 5/00

(52) U.S. Cl. CPC H05K 5/0026
USPC 361/752

(57) ABSTRACT

An electronic device includes an enclosure and a cable management apparatus. The enclosure includes a bottom wall. A printed circuit board is secured to the bottom wall. The printed circuit board includes a connector. The cable management apparatus includes a first plate and a second plate. The cable managing apparatus is mounted on the printed circuit board. The second plate is located above the connector. A cable channel is surrounded by the first plate and the second plate.

### BACKGROUND

1. Technical Field

The present disclosure relates to electronic devices, and more particularly to an electronic device with a cable management apparatus.

2. Description of Related Art

Many electronic devices, such as computers, have multiple cables. The cables may include, for example, power cables, data cables, communication lines, and keyboard lines. Therefore, it is desirable to include some type of cable management apparatus, such as a binding accessory that allows the various cables to be collected together and attached in a position to improve the use of space and the ease of visual examination inside an electronic device. However, the binding accessories of related art are not suited for temporary use in securing cables, and the binding accessories may be damaged when cables have to be replaced or re-routed.

Therefore, there is room for improvement within the art.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of the embodiments. Moreover, in the drawings, like reference numerals designate corresponding parts throughout the several views.

FIG. 1 is an exploded and isometric view of an electronic device with a cable management apparatus in accordance with an embodiment.

FIG. 2 is another exploded and isometric view of the electronic device with a cable management apparatus of FIG. 1.

FIG. 3 is an assembled view of the electronic device of FIG. 1.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean “at least one”.

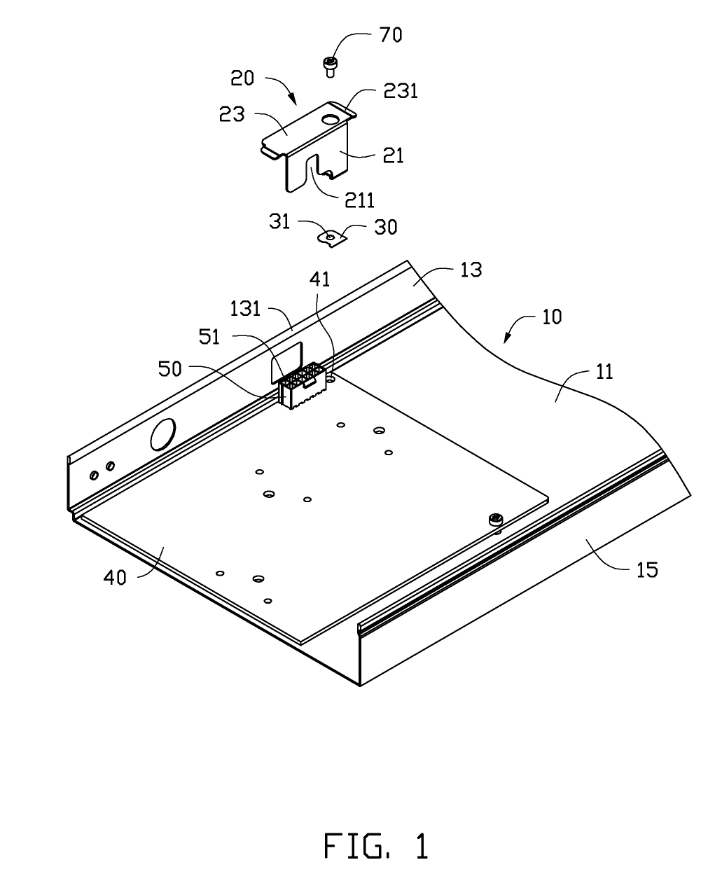

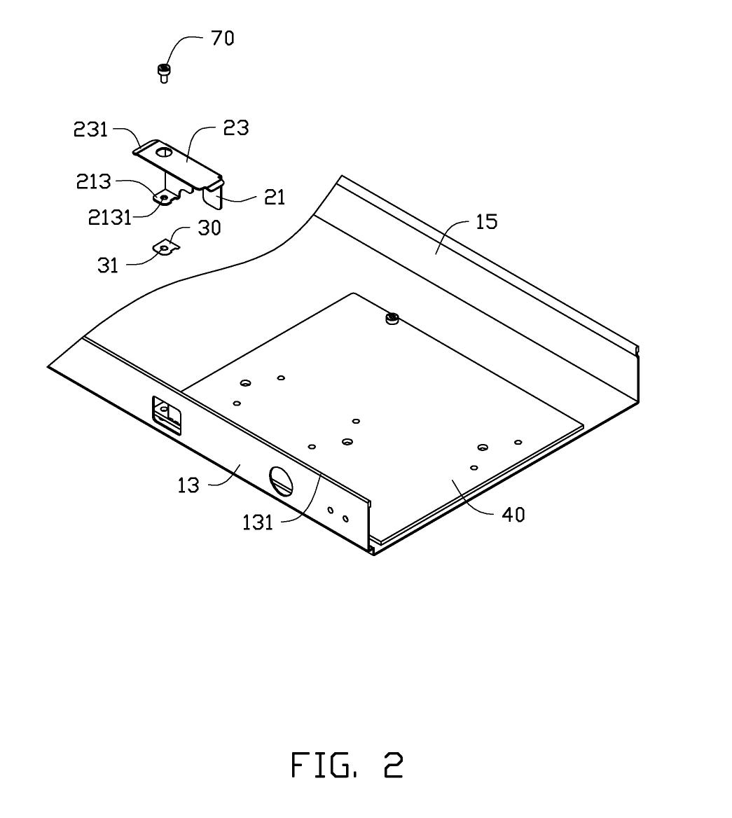

Referring to FIGS. 1 and 2, an electronic device in accordance with an embodiment includes an enclosure 10, a cable management apparatus 20, and an insulating piece 30. In one embodiment, the enclosure 10 is a server enclosure.

The enclosure 10 includes a bottom wall 11, a first sidewall 13, and a second sidewall 15. The first sidewall 13 and the second sidewall 15 are perpendicularly connected to opposite edges of the bottom wall 11. The first sidewall 13 is parallel to the second sidewall 15. A top edge of the first sidewall 13 is bent to form a flange 131.

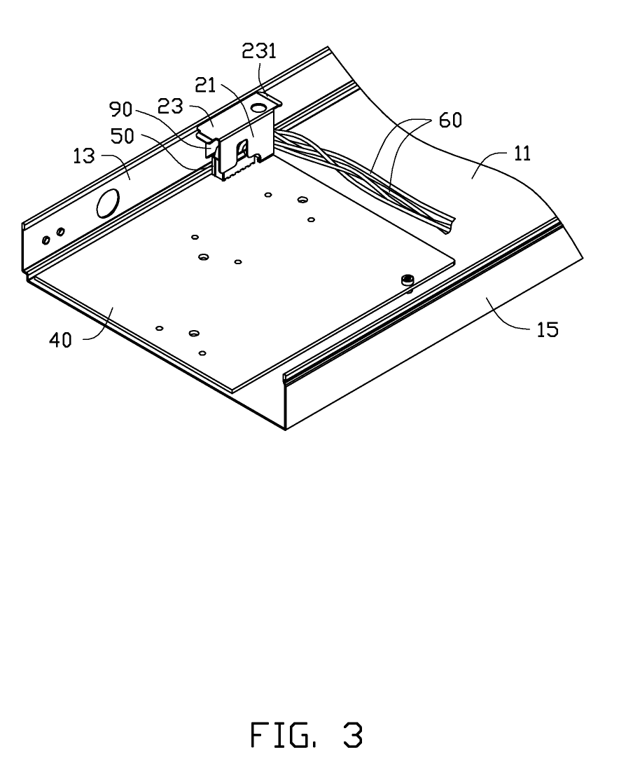

A printed circuit board (PCB) 40 is mounted on the bottom wall 11. A connector 50 is mounted on the PCB 40. The connector 50 is located adjacent the first sidewall 13. The connector 50 includes a plurality of connection holes 51 for connecting cables 60 (referring to FIG. 3). The PCB 40 defines a mounting hole 41 which is near to the connector 50.

The cable management apparatus 20 includes a first plate 21 and a second plate 23, perpendicularly connected to the first plate 21. The first plate 21 defines a cutout 211. The cutout 211 is used to receive cables 60 extending therethrough. A securing piece 213 extends from a bottom edge of the first plate 21. The securing piece 213 defines a securing hole 2131. The securing piece 213 is parallel to the second plate 23. The second plate 23 includes a pair of handles 213.

The insulating piece 30 defines a through hole 31 corresponding to the mounting hole 41 of the PCB 40.

Referring to FIG. 3, in assembly of the cable management apparatus 20 in the enclosure 10, the insulating piece 30 is firstly placed on the PCB 40. Then, the through hole 31 is aligned with the mounting hole 41. The securing piece 213 of the cable management apparatus 20 is located on the insulating piece 30 with the securing piece 213 aligned with the through hole 31. The first plate 21 abuts against one side of the connector 50 to restrict the connector 50 between the first plate 21 and the first sidewall 13. The second plate 23 is located above the connector 50 and abuts the flange 131 of the first sidewall 13. A screw 70 is extended through the securing hole 2131 and the through hole 31 and screwed into the mounting hole 41 to mount the cable management apparatus 20 on the PCB 40. Then, a cable channel 90 is formed among the first sidewall 13, the first plate 21, and the second plate 23 of the cable management apparatus 20.

After the cables 60 are connected to the connector 50, the cables 60 are received in and guided by the cable channel 90. Therefore, the cables 60 are secured by the cable management apparatus 20 and extend out of the cable channel 90 via the cutout 211 or along the first sidewall 13.

It is to be understood, however, that even though numerous characteristics and advantages of the embodiments have been set forth in the foregoing description, together with details of the structure and functions of the embodiments, the disclosure is illustrative only, and changes may be made in detail, especially in the matters of shape, size, and arrangement of parts within the principles of the present disclosure to the full extent indicated by the broad general meaning of the terms in which the appended claims are expressed.

What is claimed is:

1. An electronic device, comprising:
an enclosure comprising a bottom wall, a printed circuit board secured to the bottom wall, the printed circuit board comprising a connector; and
a cable management apparatus comprising a first plate and a second plate, the cable managing apparatus mounted on the printed circuit board, the second plate located above the connector, and a cable channel surrounded by the first plate and the second plate.

2. The electronic device of claim 1, wherein the enclosure further comprises a first sidewall connected to the bottom wall, the first sidewall comprises a flange, and the second plate abuts the flange.

3. The electronic device of claim 2, wherein the first plate is perpendicularly connected to the second plate, and the first plate abuts one side of the connector.

4. The electronic device of claim 3, wherein the first plate defines a cutout, and the cutout communicates with the cable channel.

5. The electronic device of claim 1, wherein a securing piece extends from a bottom edge of the first plate, the securing piece defines a securing hole, the printed circuit board defines a mounting hole, the securing hole is aligned to the mounting hole, and a screw is secured in the mounting hole and the securing hole.

6. The electronic device of claim 5, wherein an insulating piece is sandwiched between the securing piece and the printed circuit board.

7. The electronic device of claim 6, wherein a through hole is defined in the insulating piece, and the screw is inserted through the through hole.

8. An electronic device, comprising:
an enclosure comprising a bottom wall and a sidewall connected to an edge of the bottom wall, a printed circuit board located on the bottom wall, the printed circuit board comprising a connector which is located adjacent the sidewall; and
a cable management apparatus comprising a first plate and a second plate, the first plate defining a cutout, the cable managing apparatus mounted on the printed circuit board, a cable channel surrounded among the sidewall, the first plate, and the second plate, the cable channel located above the connector, the cable channel communicating with the cutout.

9. The electronic device of claim 8, wherein the sidewall comprises a flange, and the second plate abuts the flange.

10. The electronic device of claim 9, wherein the first plate is perpendicularly connected to the second plate, and the first plate abuts one side of the connector.

11. The electronic device of claim 8, wherein a securing piece extends from a bottom edge of the first plate, the securing piece defines a securing hole, the printed circuit board defines a mounting hole, the securing hole is aligned to the mounting hole, and a screw is secured in the mounting hole and the securing hole.

12. The electronic device of claim 11, wherein an insulating piece is sandwiched between the securing piece and the printed circuit board.

13. The electronic device of claim 12, wherein a through hole is defined in the insulating piece, and the screw is extended through the through hole.
